(19) United States
(12) Patent Application Publication
(10) Pub. No.: US 2019/0260361 A1
(43) Pub. Date: Aug. 22, 2019

(54) INPUT BUFFER WITH LOW STATIC CURRENT CONSUMPTION

(71) Applicant: TEXAS INSTRUMENTS INCORPORATED, Dallas, TX (US)

(72) Inventors: Markus Georg ROMMEL, Freising (DE); Konrad WAGENSOHNER, Mauern (DE)

(21) Appl. No.: 16/275,933

(22) Filed: Feb. 14, 2019

Related U.S. Application Data
(60) Provisional application No. 62/632,234, filed on Feb. 19, 2018.

(51) Int. Cl. H03K 3/3565; H03K 3/037; H03K 3/356

(52) U.S. Cl. CPC H03K 3/3565; H03K 3/356008; H03K 3/0377

(57) ABSTRACT

A circuit includes a first pair of transistors coupled in series between a supply voltage node and an output node and a second pair of transistors coupled in series between the output node and a ground node. The circuit further includes a first diode-connected transistor coupled between a first node between the first pair of transistors and the output node, and a second diode-connected transistor coupled between a second node between the second pair of transistors and the output node.

### RELATED APPLICATIONS

This application claims priority to U.S. Provisional Application No. 62/632,234, filed Feb. 19, 2018, which is hereby incorporated by reference.

### BACKGROUND

A Schmitt Trigger (ST) is a bistable circuit in which the output changes state when the input rises above an upper threshold and again changes state when the input falls below a lower threshold. An ST thus includes hysteresis. The difference between the upper threshold voltage and the lower threshold voltage is the hysteresis voltage. ST circuits are often used as input buffers to an integrated circuit. As an input buffer, the ST circuit differentiates its input signal being a logic “high” versus a logic “low”.

A trend exists towards lower and lower supply voltages. For example, 1.8 V supply voltages are being pushed down to 1.2 V supply voltages. The downward pressure in supply voltages presents a problem for ST circuits in that the hysteresis voltage for many ST circuits is too large to accommodate lower desired supply voltages.

### SUMMARY

In some examples, a circuit includes a first pair of transistors coupled in series between a supply voltage node and an output node, and a second pair of transistors coupled in series between the output node and a ground node. The circuit further includes a first diode-connected transistor coupled between a first node between the first pair of transistors and the output node, and a second diode-connected transistor coupled between a second node between the second pair of transistors and the output node.

In another example, a circuit includes a first transistor having a first control input, and a second transistor coupled to the first transistor. The second transistor includes a second control input. A controller is configured to control the first and second control inputs. The circuit further includes an input buffer coupled to the controller. The input buffer includes a first pair of transistors coupled in series between a supply voltage node and an output node, a second pair of transistors coupled in series between the output node and a ground node, a first diode-connected transistor coupled between a first node between the first pair of transistors and the output node, and a second diode-connected transistor coupled between a second node between the second pair of transistors and the output node.

In yet another example, a circuit includes first through fourth transistors, The first transistor has a first control input and first and second current terminals. The first current terminal is coupled to a first supply voltage node. The second transistor has a second control input and third and fourth current terminals. The third current terminal is coupled to the second current terminal at a first node. The first and second control inputs are coupled to an input node. The first and second transistors are configured to pull the output node to a logic high level responsive to a voltage on the input node being below a first voltage threshold. The third transistor has a third control input and fifth and sixth current terminals. The fifth current terminal is coupled to the fourth current terminal at an output node. The fourth transistor has a fourth control input and seventh and eighth current terminals. The seventh current terminal is coupled to the sixth current terminal at a second node. The third and fourth control inputs are coupled to the input node. The eighth current terminal is coupled to a second supply voltage node. The third and fourth transistors are configured to pull the output node to a logic low level responsive to a voltage on the input node being above a second voltage threshold. The circuit also includes first and second diode-connected transistors. The first diode-connected transistor is coupled between the output node and the first node. When on, the first diode-connected transistor is configured to impose a voltage on the first node that is lower than the voltage on the first current terminal. The second diode-connected transistor is coupled between the output node and the second node. The second diode-connected transistor, when on, is configured to impose a voltage on the second node that is higher than the voltage on the eighth current terminal.

### BRIEF DESCRIPTION OF THE DRAWINGS

For a detailed description of various examples, reference will now be made to the accompanying drawings in which:

FIG. 1 illustrates a Schmitt Trigger circuit in accordance with an example.

FIG. 2 provides a timing diagram for various signals with the Schmitt Trigger circuit of FIG. 1.

FIG. 3 provides simulation results showing that the hysteresis voltage of the disclosed Schmitt Trigger circuit is lower than the hysteresis voltage of conventional Schmitt Trigger circuits.

FIG. 4 shows a system in which the disclosed Schmitt Trigger circuit is used.

FIG. 5 shows a voltage converter in which the disclosed Schmitt Trigger circuit is used.

### DETAILED DESCRIPTION

This disclosure is related to a modified Schmitt Trigger circuit. The modification causes the hysteresis voltage to be smaller than for a conventional ST circuit. For example, rather than having an upper threshold of 1.2 V and a lower threshold of 0.4 V for a conventional ST circuit (i.e., a 800 mV hysteresis voltage), the ST circuit described herein is characterized by a smaller hysteresis voltage (e.g., 80-250 mV). As such, the ST circuit described herein is more suitable for lower voltage operation (e.g., 1.2 V instead of 1.8 V). Further, the quiescent current consumption the described ST circuit is very low.

The description herein refers to transistors. A transistor includes a control input and a pair of current terminals. The control input and current terminals of a metal oxide semiconductor field effect transistor are the transistor's gate, drain, and source terminals, respectively. The control input and current terminals of a bipolar junction transistor are the transistor's base, emitter, and collector terminals, respectively.

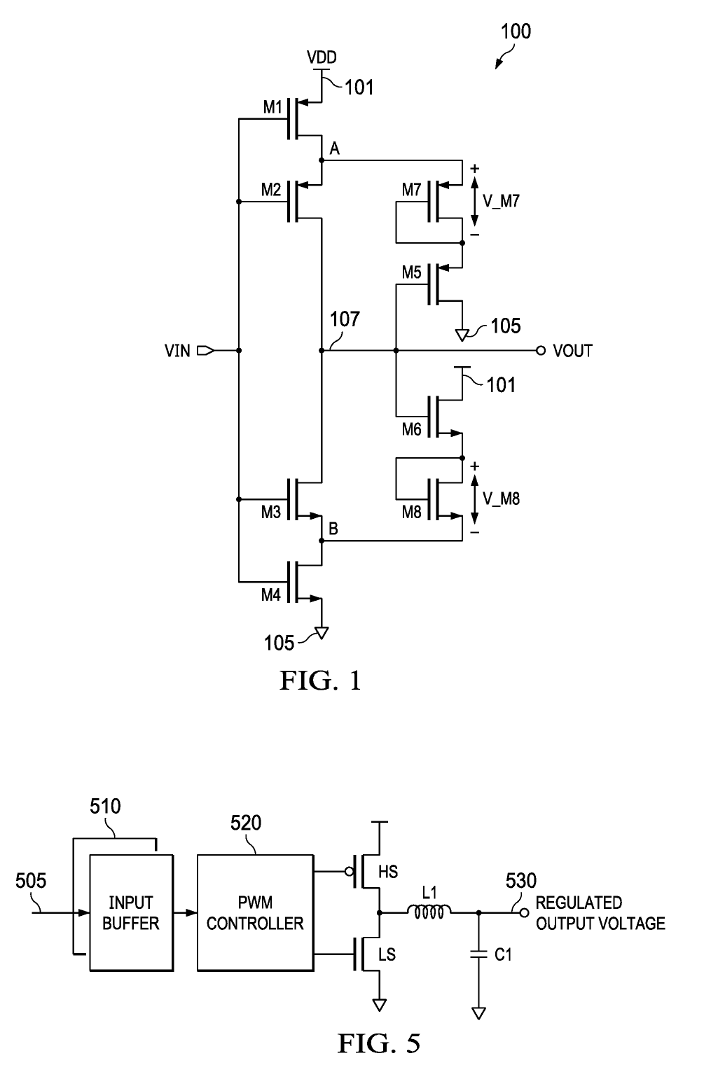

FIG. 1 is a schematic of an example ST circuit 100. This example ST circuit 100 includes transistors M1, M2, M3, M4, M5, M6, M7, and M8. In this example, M1, M2, M5, and M7 comprise p-type metal oxide semiconductor field effect transistors (pMOS) and M3, M4, M6, and M8 comprise n-type metal oxide semiconductor field effect transistors (nMOS). In other example implementations, any or all of M1-M8 can be implemented with other types of MOS devices-pMOS substituted for nMOS, and vice versa. Further, any or all of M1-M8 can be implemented with other types of transistors such as bipolar junction transistors.

M1 and M2 comprise a series-connected pair of transistors. This series pair is connected between a supply voltage node 101 (VDD) and an output voltage node 107 (VOUT). Similarly, M3 and M4 also comprise a series-connected pair of transistors connected between the output voltage node 107 and a ground node 105. The output node 107 is the node interconnecting the drains of M2 and M3. The gates of M5 and M6 are connected to the output node 107. The drain of M5 is connected to the ground node 105 and the drain of M6 is connected to the supply voltage node 101.

M7 and M8 comprise diode-connected transistors. M7 and M8 are oppositely doped (e.g., M7 is a pMOS device and M8 is an nMOS device). The gates of M7 and M8 are connected to their respective drains. The source of M7 is connected to the node interconnecting the drain of M1 to the source of M2 (node A). The source of M8 is connected to the node interconnecting the drain of M4 to the source of M2 (node B). Diode-connected transistors M7 and M8 may comprise low threshold voltage transistors, which are transistors that have a threshold voltage that is less than the threshold voltage of a standard transistor. An example of the threshold voltage for a low threshold voltage transistor is between 0.3V and 0.5V.

Each of the diode-connected transistors M7 and M8 generates a bias voltage (e.g., 0.7 V). The bias voltage from M7 is referred to as V_M7 and the bias voltage from M8 is V_M8. When M6 and M8 are on, which is the case when VOUT is high, the voltage on node B is VDD minus V_M8 (e.g., VDD−0.7V). Similarly, when M5 and M7 are on, which is the case when VOUT is low, the voltage on node A is the ground potential plus V_M7 (e.g., GND+0.7V).

When VIN is low (e.g., ground potential), pMOS devices M1 and M2 are on, and nMOS devices M3 and M4 are off. With M1 and M2 being on, the output node 107 is pulled up to VDD through M1 and M2, and thus VOUT is high. When VIN is high (e.g., VDD), M1 and M2 are off, and M3 and M4 are on. With M3 and M4 being on, the output node 107 is pulled low to ground through M3 and M4 and thus VOUT is low. Transistors M5-M8 cause the circuit to implement an upper threshold and a lower threshold to thereby provide hysteresis. If VIN is low (and VOUT is high), VOUT will not transition to a logic low signal level until VIN exceeds the upper threshold, at which time VOUT becomes a low signal level. As VIN then decreases, VOUT will remain low until VIN falls below the lower threshold, at which time VOUT will be forced high.

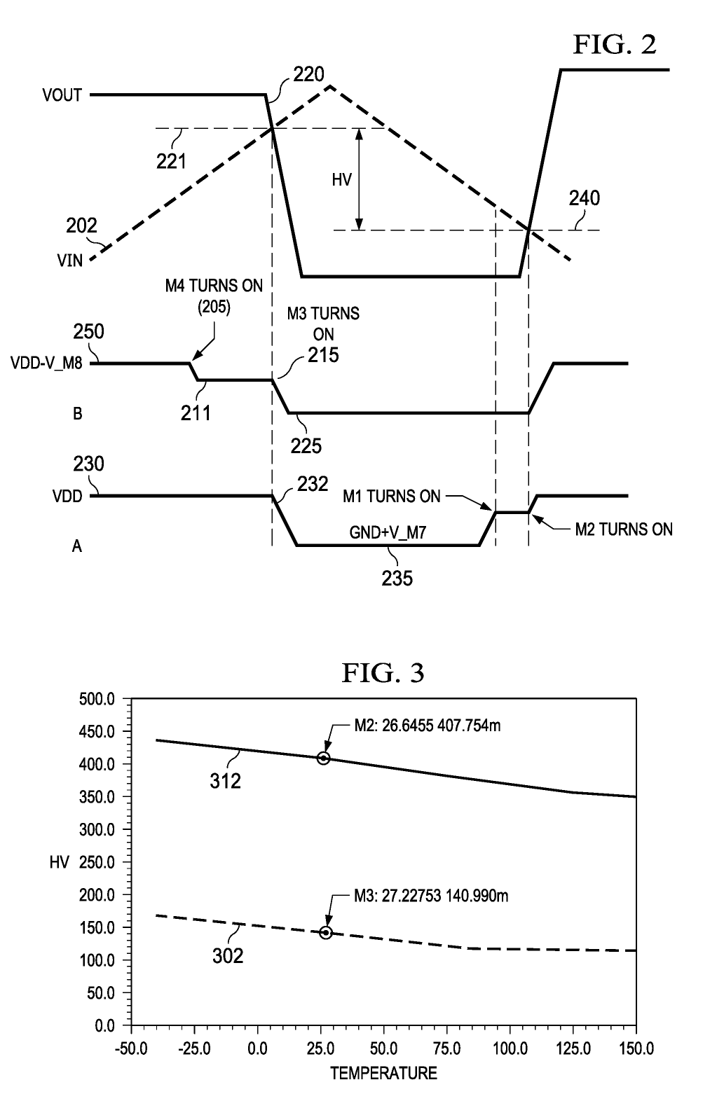

FIG. 2 provides a timing diagram illustrating the operation of the ST circuit of FIG. 1. The signals shown in FIG. 2 include VIN as it ramps up and then back down, VOUT, the voltage on node B, and the voltage on node A. Initially, at 202, VIN is low (but increasing) and VOUT is high as explained above. M3 and M4 are off. With VOUT being high, M6 and M8 are turned on, and thus the node B voltage is pulled high to VDD less the bias voltage V_M8. At this point, the voltage on the source of M3 (the node B voltage) is VDD-V_M8 which is higher than the voltage on the source of M4 (ground).

As VIN continues to ramp up as shown, M4 will turn on (as shown at 205) before M3 turns on because the source voltage for M4 is smaller than the source voltage for M3, and thus M4 is caused to be turned on with a smaller gate voltage (VIN) than for M3. Once M4 turns on, the voltage on node B drops as shown at 211 due to the current flow from the supply voltage node 101 through M6, M8, and M4 to ground.

As VIN continues to increase, eventually the voltage on the gate-to-source voltage across M3 is high enough to turn M3 on as well, as indicated at 215 in FIG. 2. Once M3 turns on, the output node 107 will be pulled to ground through M3 and M4. VOUT thus transitions from high to low as shown at 220. The upper threshold level is shown at 221. With VOUT being low at this point, M6 and M8 are turned off, and the node B voltage is pulled to ground as shown at 225.

Meanwhile, while VIN is ramping up with VOUT being high, M5 and M7 are off and M1 and M2 are on, which not only pulls VOUT high but also causes the node A voltage to be high as well (VDD) as shown at 230. Upon VOUT transitioning at 220 to a low level, M5 and M7 turn on, which, as indicated at transition 232, pulls node A to the potential ground plus V_M7 as shown at 235.

FIG. 2 also illustrates the transient behavior of the circuit as VIN, which is above the upper threshold 221, begins to decrease. VOUT is low at this point. As VIN begins to decrease, the voltage on node B is low (approximately ground). Also, the voltage on node A is V_M7 above ground as shown at 235 due to M5 and M7 being on and M5 producing the bias voltage V_M7 (e.g., 0.7 V). As VIN decreases, eventually VIN falls low enough to turn on M1. The VIN voltage at which M1 is first turned on is not low enough to also turn on M2 due to the source voltage of M2 being lower (ground+V_M7) than the source voltage of M1 (VDD). As VIN decreases even further, eventually VIN drops low enough so that the gate-to-source voltage for M2 is large enough to also turn on M2, which then forces VOUT to transition high. The lower threshold for the ST circuit of FIG. 1 is shown at 240.

The difference between the upper threshold 221 and the lower threshold is the hysteresis voltage (HV) for the disclosed ST circuit. A conventional ST circuit lacks the diode-connected transistors, and thus the corresponding node B voltage at 250 is higher (VDD) than for the disclosed ST circuit (VDD-V_M8). Similarly, the corresponding node A voltage is lower (ground) for a conventional ST circuit than for the disclosed ST circuit (ground+V_M7). Because the upper threshold is lower and the lower threshold is higher for the disclosed ST circuit as compared to the thresholds for a conventional ST circuit, the HV of the disclosed ST circuit of FIG. 1 is smaller than for a conventional circuit. As such, the disclosed ST circuit can be used for lower VDD supply voltages.

FIG. 3 shows simulation results for a conventional ST circuit and for the disclosed ST circuit. The y-axis is HV in units of millivolts and the x-axis is temperature. The simulation results show that the hysteresis voltage of the disclosed ST circuit (curve 302) is significantly higher than for a conventional ST circuit (curve 312) across a range of temperatures.

The current consumption during switching operations of the ST's transistors is mainly driven by the current through transistors M5 and M6 which are directly connected to ground and VDD, respectively. For a conventional ST, the quiescent current is generally not limited by any particular circuit function. However, quiescent current of a conventional ST could be reduced by including a series resistor (instead of M7 and M8, that is, replacing each of M7 and M8 by a resistor). However, in that case the quiescent current linearly scales with the voltage across the resistors. In the ST circuit described herein (e.g., FIG. 1), diode-connected transistors are used instead of resistors. The current of a diode-connected transistor has a quadratic-dependency on the drain-to-source voltage of the transistor. Due to the quadratic dependency on voltage, the current consumption of the disclosed ST during switching is lower than for standard STs or STs with resistors instead of diode-connected transistors. Further, the use of diode-connected transistors M7 and M8 results in a smaller area circuit than if resistors were used.

In addition to lower current consumption during switching, the current decrease in combination with the smaller hysteresis voltage results in a faster decrease of quiescent current during switching events. This allows for a lower quiescent current consumption for the same input voltage VIN. Alternatively stated, the smaller hysteresis voltage provides for more precise control of the output voltage with the same current consumption.

Other types of buffer circuits include a differential pair precision comparator that includes a bias current. Such circuits are quite accurate but unfortunately have relatively high static current consumption due to the bias current needed for the comparator. As noted above, the bias current consumption of the disclosed ST circuit 100 is relatively low. Further, the disclosed ST circuit 100 does not require a comparator thereby making it a smaller area option. Yet another buffer circuit includes a conventional Schmitt Trigger and multiple inverter stages (and additional transistors) to control feedback loops from the output to the input the input. The disclosed ST 100 of FIG. 1 does not include a direct feedback loop, and thus does not need (nor include) any inverters.

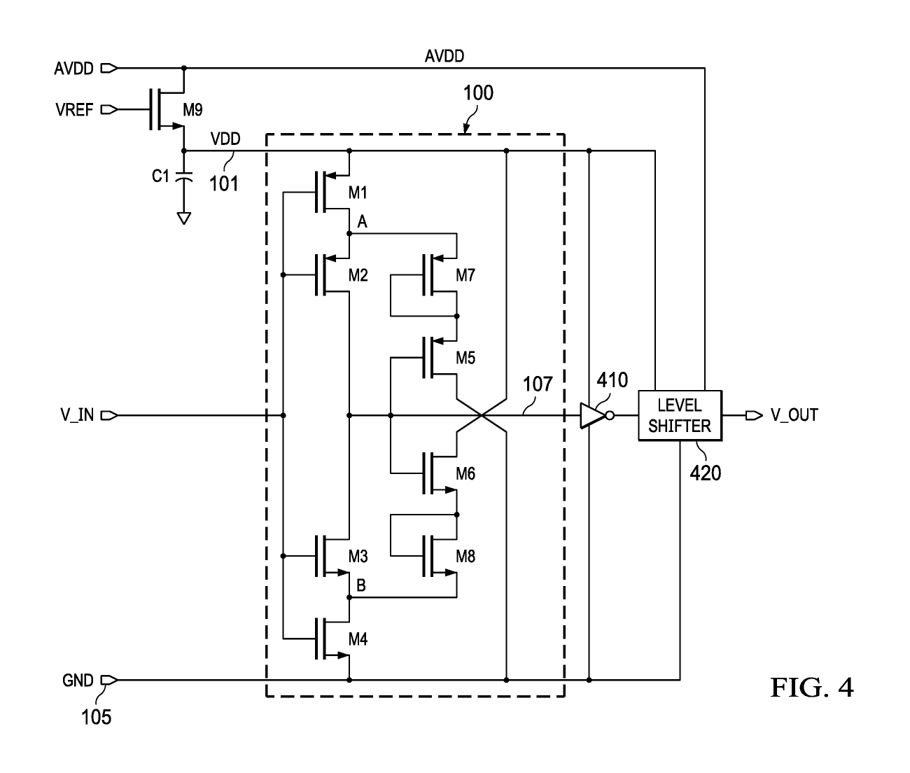

FIG. 4 illustrates a system 400 that includes the ST circuit 100 of FIG. 1. The supply voltage to the system is AVDD. A source follower transistor M9 is biased by a reference voltage (VREF). AVDD is provided to M9's drain and its source is connected to a capacitor C1. Current from AVDD flows through M9 to charge C1 to thereby provide a lower supply voltage VDD to the ST circuit 100. In this example, M9 comprises an nMOS device and may be implemented as a natural transistor, which is a transistor that has a negative or approximately zero threshold voltage. The threshold voltage of a transistor can be set by adding implants during the manufacturing process. For example, to provide a desired threshold voltage for an nMOS transistor, a suitable amount of p-type implants are added. Depending on the type and amount of implant added, a particular threshold voltage can be achieved. The combination of M9 and C1 comprises a sub-regulated voltage supply which is a voltage supply that generates a VDD level for the ST circuit 100 that is smaller than AVDD.

The output node 107 from ST circuit 100 is provided to an inverter 410, which logically inverts the voltage on node 107 and provides the inverted voltage to a level shifter 420. The inverter 410 further sharpens the edges of the output voltage from the ST circuit 100 and the level shifter adjusts the voltage to a different level.

FIG. 5 shows an example of system that uses the disclosed ST circuit 100. The system in FIG. 5 includes one or more input buffers 510, a pulse width modulation (PWM) controller 520, two power transistors (a high side (HS) FET and a low side (LS) FET), an inductor L1 and an output capacitor C1. The system of FIG. 5 comprises a voltage regulator such as a buck converter to produce a regulated output voltage. The system shown in FIG. 5 may be fabricated on a common semiconductor die (e.g., as one integrated circuit). The PWM controller 520 asserts signal to the control inputs of the HS and LS FETs (e.g., their gates). The PWM controller 520 controls the on/off state of the HS and LS FETs to cause the output voltage 530 to be regulated to a target level.

One more input signals 505 may be provided to the buck converter of FIG. 5 to control different operational aspects of the converter. For example, the input signals may include one or more of an enable signal for the converter, a mode signal to specify discontinuous conduction mode (DCM) or continuous conduction mode (CCM), etc. Each of the input buffers 510 comprises the ST circuit 100 described herein to determine whether a given input 505 is a high or a low.

In this description, the term “couple” or “couples” means either an indirect or direct connection. Thus, if a first device couples to a second device, that connection may be through a direct connection or through an indirect connection via other devices and connections. Modifications are possible in the described embodiments, and other embodiments are possible, within the scope of the claims.

What is claimed is:

1. A circuit, comprising:
a first pair of transistors coupled in series between a supply voltage node and an output node;
a second pair of transistors coupled in series between the output node and a ground node;
a first diode-connected transistor coupled between a first node between the first pair of transistors and the output node; and
a second diode-connected transistor coupled between a second node between the second pair of transistors and the output node.

2. The circuit of claim 1, further comprising a third transistor coupled between the first diode-connected transistor and the output node, and a third transistor coupled between the second diode-connected transistor and the output node.

3. The circuit of claim 1, wherein the first and second diode-connected transistors are oppositely doped.

4. The circuit of claim 1, wherein the first diode-connected transistor is a low threshold voltage transistor.

5. The circuit of claim 1, wherein the second diode-connected transistor is a low threshold voltage transistor.

6. The circuit of claim 5, wherein the first diode-connected transistor is a low threshold voltage transistor.

7. The circuit of claim 1, further comprising a sub-regulated voltage supply circuit coupled to the supply voltage node.

8. A circuit, comprising:
a first transistor having a first control input;
a second transistor coupled to the first transistor, the second transistor including a second control input;
a controller configured to control the first and second control inputs; and
an input buffer coupled to the controller, the input buffer including:
a first pair of transistors coupled in series between a supply voltage node and an output node;
a second pair of transistors coupled in series between the output node and a ground node;
a first diode-connected transistor coupled between a first node between the first pair of transistors and the output node; and
a second diode-connected transistor coupled between a second node between the second pair of transistors and the output node.

9. The circuit of claim 8, further comprising a third transistor coupled between the first diode-connected transistor and the output node, and a fourth transistor coupled between the second diode-connected transistor and the output node.

10. The circuit of claim 8, wherein the first and second diode-connected transistors are oppositely doped.

11. The circuit of claim 8, wherein the first diode-connected transistor is a low threshold voltage transistor.

12. The circuit of claim 8, wherein the second diode-connected transistor is a low threshold voltage transistor.

13. The circuit of claim 12, wherein the first diode-connected transistor is a low threshold voltage transistor.

14. The circuit of claim 8, further comprising a sub-regulated voltage supply circuit coupled to the supply voltage node.

15. A circuit, comprising:
a first transistor having a first control input and first and second current terminals, the first current terminal coupled to a first supply voltage node;
a second transistor having a second control input and third and fourth current terminals, the third current terminal coupled to the second current terminal at a first node, the first and second control inputs coupled to an input node, and wherein the first and second transistors are configured to pull the output node to a logic high level responsive to a voltage on the input node being below a first voltage threshold;
a third transistor having a third control input and fifth and sixth current terminals, the fifth current terminal coupled to the fourth current terminal at an output node;
a fourth transistor having a fourth control input and seventh and eighth current terminals, the seventh current terminal coupled to the sixth current terminal at a second node, the third and fourth control inputs coupled to the input node, the eighth current terminal coupled to a second supply voltage node, and wherein the third and fourth transistors are configured to pull the output node to a logic low level responsive to a voltage on the input node being above a second voltage threshold;
a first diode-connected transistor coupled between the output node and the first node, wherein the first diode-connected transistor, when on, is configured to impose a voltage on the first node that is lower than the voltage on the first current terminal; and
a second diode-connected transistor coupled between the output node and the second node, wherein the second diode-connected transistor, when on, is configured to impose a voltage on the second node that is higher than the voltage on the eighth current terminal.

16. The circuit of claim 15, further comprising a fifth transistor coupled between the first diode-connected transistor and the output node.

17. The circuit of claim 16, further comprising a sixth transistor coupled between the second diode-connected transistor and the output node.

18. The circuit of claim 15, further comprising a fifth transistor coupled between the second diode-connected transistor and the output node.

19. The circuit of claim 15, wherein responsive to an increase of an input voltage on the input node, the fourth transistor turns on before the third transistor turns on.

20. The circuit of claim 15, wherein responsive to a decrease of an input voltage on the input node, the first transistor turns on before the second transistor turns on.
